(19) United States
(12) Patent Application Publication
(10) Pub. No.: US 2024/0276856 A1
(43) Pub. Date: Aug. 15, 2024

(54) PREPARATION METHOD OF LIGHT-EMITTING DEVICE, LIGHT-EMITTING DEVICE AND LIGHT-EMITTING APPARATUS

(71) Applicants: Beijing BOE Technology Development Co., Ltd., Beijing (CN); BOE Technology Group Co., Ltd., Beijing (CN)

(72) Inventor: Tieshi Wang, Beijing (CN)

(73) Assignees: Beijing BOE Technology Development Co., Ltd., Beijing (CN); BOE Technology Group Co., Ltd., Beijing (CN)

(21) Appl. No.: 17/925,360

(22) PCT Filed: Dec. 20, 2021
(86) PCT No.: PCT/CN2021/139668

§ 371 Date: Nov. 15, 2022

(51) Int. Cl. H10K 71/12; H10K 50/115; H10K 50/15; H10K 59/35; H10K 102/00

(52) U.S. Cl. CPC H10K 71/125; H10K 50/115; H10K 50/156; H10K 59/35; H10K 2102/351

(57) ABSTRACT

Disclosed are a preparation method of a light-emitting device, a light-emitting device, and a light-emitting apparatus. The light-emitting device includes a substrate, and a first electrode and a carrier assist layer that are arranged in stack on a side of the substrate, the first electrode is arranged adjacent to the substrate, and the preparation method includes: providing a substrate; forming the first electrode on a side of the substrate, the first electrode being provided with a patterned shape; by adopting an electrochemical polymerization method, placing the first electrode in an electrolyte solution as a positive electrode or a working electrode, and polymerizing polymerizable monomers in the electrolyte solution at the surface of the first electrode to form the carrier assist layer, where the material of the carrier assist layer includes a polymer of the polymerizable monomers.

### TECHNICAL FIELD

The present disclosure relates to the field of semiconductor technology, and in particular, to a preparation method of a light-emitting device, a light-emitting device, and a light-emitting apparatus.

### BACKGROUND

The organic light-emitting diode (OLED) has advantages of self-emission, wide viewing angle, fast response, high emission efficiency, low operating voltage and simple processing, and it is known as a next generation “star” light-emitting device.

The quantum dot light-emitting diode (QLED) has narrower emission spectrum, purer display color and broader color gamut, and therefore QLED has attracted much attention from display industry and become a powerful candidate for next generation display technology.

### SUMMARY

The present disclosure provides a preparation method of a light-emitting device, where the light-emitting device includes a substrate, and a first electrode and a carrier assist layer that are arranged in stack on a side of the substrate, and the first electrode is arranged adjacent to the substrate. The preparation method includes:

providing a substrate;

forming the first electrode on a side of the substrate, the first electrode being provided with a patterned shape; and

by adopting an electrochemical polymerization method, placing the first electrode in an electrolyte solution as a positive electrode or a working electrode, and polymerizing polymerizable monomers in the electrolyte solution at the surface of the first electrode to form the carrier assist layer, where the material of the carrier assist layer includes a polymer of the polymerizable monomers.

In an alternative implementation, the polymerizable monomers include at least one of thiophenes and derivatives thereof.

In an alternative implementation, the polymerizable monomers include at least one of 3,4-dibromothiophene, 3-dodecylthiophene, a-terthiophene, 3-bromo-4-methylthiophene, 3-hexylthiophene, 3-methoxythiophene, 3-acetylthiophene, 3-ethylthiophene, 3,4-ethylenedioxythiophene, 3-methoxythiophene, 3-thiophenemalonic acid, thiophene-3-ethyl acetate, 3-bromothiophene, trans-3-(3-thienyl) acrylic acid. 3-iodothiophene, 3-n-hexadecylthiophene, thiophene-3-carbonitrile, 3-chlorothiophene, methyl 3-thiophenecarboxylate, 3-thiophenemethylamine, 3-butylthiophene, 3-bromomethylthiophene, 3-thiophenecarbaldehyde, 3-methylthiophene, 3-thiophenecarboxylic acid, 3-n-octadecylthiopbene, 4-aminobenzothiophene, 3-n-undecylthiophene, thiophene-3-acetonitrile, 3-n-propylthiophene, 3,3′-bithiophene, 2,2′-dithiophene, 3-ethyuylthiophene, 3-(aminomethyl) thiophene hydrochloride, 3,4-dicyanothiophene. 3,4-thiophenedicarboxylic acid, 3-heptylthiophene, 3-n-octylthiophene, 3-thiophenemethanol and trithiophene.

In an alternative implementation, the electrolyte solution further includes a mixed solution of diethyl ether and boron trifluoride diethyl ether, where a volume ratio of the diethyl ether to the boron trifluoride diethyl ether is 4:1.

In an alternative implementation, a concentration of the polymerizable monomers in the electrolyte solution is greater than or equal to 0.01 mol/L, and less than or equal to 0.5 mol/L.

In an alternative implementation, a potential on the first electrode is a constant potential, and the constant potential is greater than or equal to 0.5 V and less than or equal to 5 V.

In an alternative implementation, the electrolyte solution is further provided with a negative electrode corresponding to the positive electrode or an auxiliary electrode corresponding to the working electrode, where the material of the negative electrode and the auxiliary electrode is a metal, a metal alloy or a non-metal conductor with stable electrochemical properties.

In an alternative implementation, forming the carrier assist layer includes: forming the carrier assist layer under protection of an inert gas atmosphere.

In an alternative implementation, the step of forming the first electrode on a side of the substrate includes:

by using a patterning process, forming a patterned first electrode on a side of the substrate;

the step of polymerizing polymerizable monomers in the electrolyte solution at the surface of the first electrode to form the carrier assist layer includes:

polymerizing polymerizable monomers in the electrolyte solution at the surface of the patterned first electrode to form the carrier assist layer in the same pattern as the first electrode.

The present disclosure provides a light-emitting device prepared with the preparation method according to any of the above.

In an alternative implementation, a thickness of the carrier assist layer is greater than or equal to 5 nm, and less than or equal to 20 nm.

In an alternative implementation, the light-emitting device further includes a light-emitting layer arranged on a side of the carrier assist layer away from the substrate, and a second electrode arranged on a side of the light-emitting layer away from the substrate.

In an alternative implementation, the light-emitting device further includes at least one of following film layers: a hole transport layer, an electron transport layer, and an electron injection layer; where

the hole transport layer is arranged between the carrier assist layer and the light-emitting layer; and the electron transport layer and the electron injection layer are arranged in stack

between the light-emitting layer and the second electrode, and the electron transport layer is arranged adjacent to the light-emitting layer.

In an alternative implementation, the material of the light-emitting layer includes quantum dots.

The present disclosure provides a light-emitting apparatus including the light-emitting device according to any of the above.

The above description is merely a summary of technical solutions of the present disclosure, which can be carried out according to the contents of the specification in order to make technical means of the present disclosure more clearly understood, and in order to make the above and other objects, features and advantages of the present disclosure more easily understood, particular implementations of the present disclosure are set forth below.

### BRIEF DESCRIPTION OF THE DRAWINGS

In order to illustrate the embodiments of the present disclosure or the technical solutions in related art more clearly, a brief description will be given below to the accompanying drawings to be used in description of embodiments or related art, where it is obvious that the drawings in the following description are only some embodiments of the present disclosure, and a person skilled in the art would have been able to obtain other drawings according to these drawings without involving any creative effort. It is noted that the scale in the drawings is merely schematic and do not represent the actual scale. In the drawings, the thickness of layers, films, panels, regions and the like may be exaggerated for clarity. Exemplary implementations are described herein with reference to cross-sectional views that are schematic illustrations of idealized implementations. As such, deviations from the shapes in the drawings as a result of e.g., manufacturing techniques and/or tolerances are to be expected. Thus, implementations described herein should not be construed as being limited to the particular shapes of regions shown herein, but are to include deviations in shapes that result, for example, from manufacturing. For example, regions illustrated or described as flat may typically have rough and/or non-linear features. Moreover, the corners illustrated as sharp may be rounded instead. Thus, the regions shown in the drawings are schematic in nature and their shapes are not intended to illustrate precise shapes of the regions and are not intended to limit the scope of the claims.

As used herein, the term “and/or” includes any and all combinations of one or more of the recited items related. It will be further understood that the term “comprise” or “include”, when used in this specification, indicates the presence of stated features, regions, entirety, steps, operations, elements, and/or components, without excluding the presence or addition of one or more additional features, regions, entirety, steps, operations, elements, components, and/or groups thereof.

FIG. 1 schematically shows a flow chart of steps of a preparation method of a light-emitting device;

FIG. 2 schematically shows a schematic diagram of cross-sectional structure of a light-emitting device in preparation process;

FIG. 3 schematically shows a schematic diagram of preparation of a carrier assist layer with an electrochemical polymerization method;

FIG. 4 schematically shows a sectional view and a surface view of a carrier assist layer prepared with spin coating process;

FIG. 5 schematically shows a sectional view and a surface view of a carrier assist layer prepared with an electrochemical polymerization method;

FIG. 6 schematically shows a graph comparing current densities of light-emitting devices prepared with a spin coating process and an electrochemical polymerization method, respectively;

FIG. 7 schematically shows a graph comparing current efficiencies of light-emitting devices prepared with a spin coating process and an electrochemical polymerization method, respectively;

FIG. 8 schematically shows schematic diagrams of planar structures of several patterned first electrodes;

FIG. 9 schematically shows schematic diagrams of planar structures of several patterned carrier assist layers; and

FIG. 10 schematically shows schematic diagrams of several pixel structures.

### DETAILED DESCRIPTION OF THE EMBODIMENTS

In order to make clearer the purposes, technical solutions, and advantages of embodiments of the present disclosure, the technical solutions in the embodiments of the present disclosure will now be described more clearly and fully hereinafter with reference to the accompanying drawings in the embodiments of the present disclosure. It is obvious that the embodiments described are a few, but not all embodiments of the disclosure. Based on the embodiments of the present disclosure, all other embodiments obtained by a person of ordinary skill in the art without inventive effort shall fall within the protection scope of the present disclosure.

Currently, inkjet printing technology is the most attractive patterning process in the preparation of light-emitting devices. In the related art, a hole injection layer is generally provided in a light-emitting device such as an OLED, a QLED, etc., to improve hole injection efficiency. Since hole injection materials are mostly polymeric materials, it is difficult to develop ink, and polymeric ink may easily clog nozzles, making it difficult to form patterned hole injection layers with inkjet printing technology.

In the related art, in order to increase the solubility of a polymer and impart solution processing characteristics to the polymer, a co-solvent is generally added. However, the addition of the co-solvent leads to a deterioration of the conductivity of the hole injection material, and the introduction of the co-solvent reduces the stability of the solution itself, and the eventually formed hole injection film layer also has a problem of poor density.

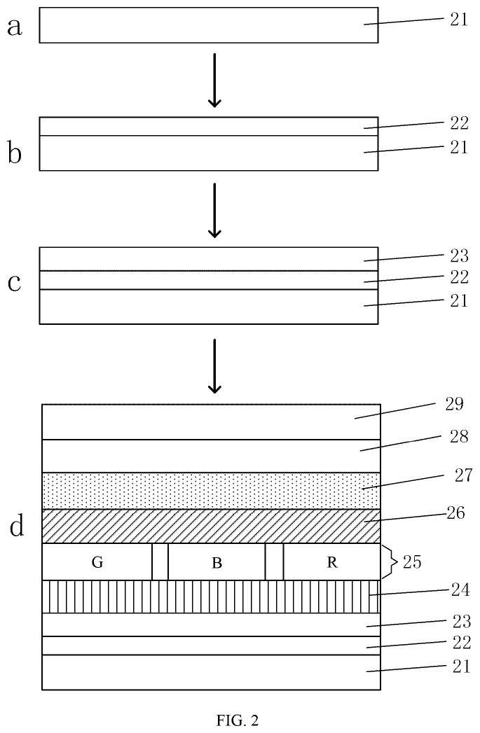

The present disclosure provides a preparation method of a light-emitting device, where the light-emitting device includes a substrate 21, and a first electrode 22 and a carrier assist layer 23 that are arranged in stack on a side of the substrate 21, the first electrode 22 is arranged adjacent to the substrate 21, as shown in c in FIG. 2.

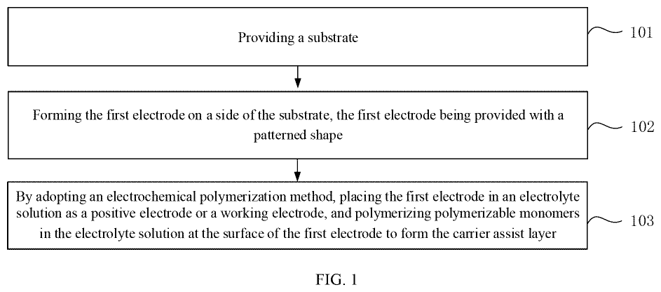

Referring to FIG. 1, a flow chart of steps of a preparation method of a light-emitting device is shown. The preparation method includes the following steps.

Step 101, providing a substrate 21, as shown in a in FIG. 2.

The substrate 21 may be, for example, glass, a polyimide film or a silicon wafer, which is not limited in the disclosure.

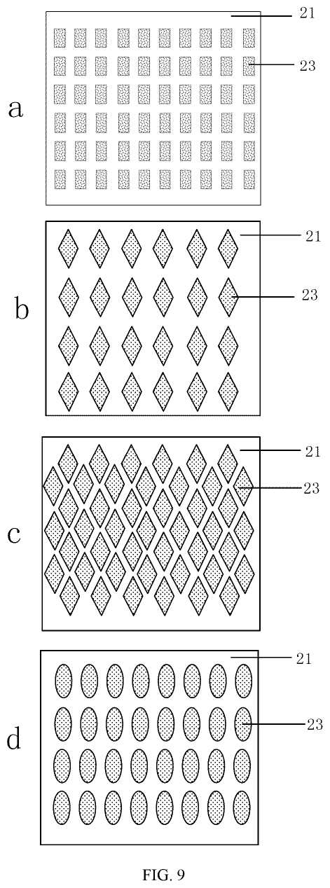

Step 102, forming a first electrode 22 on a side of the substrate 21, where the first electrode 22 may have a patterned shape. Referring to b in FIG. 2, a schematic diagram of cross-sectional structure of the light-emitting device formed with the first electrode is shown; and referring to FIG. 8, schematic diagrams of planar structures of several patterned first electrodes are shown.

The first electrode 22 may be a transmissive electrode or a transflective electrode. If the first electrode 22 is a transflective electrode or a reflective electrode, the first electrode 22 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (e.g. a mixture of Ag and Mg). In one or more implementations, the first electrode 22 may have a multi-layer structure including a reflective layer and/or a transflective layer formed by using any of the materials described above, and a transparent conductive layer formed by using indium tin oxide (ITO), indium zinc oxide (IZO), zinc oxide (ZnO), indium tin zinc oxide (ITZO), etc. For example, the first electrode 22 may be a multi-layer metal layer, and may have a laminated structure of ITO/Ag/ITO.

Step 103, by adopting an electrochemical polymerization method, placing the first electrode 22 in an electrolyte solution as a positive electrode or a working electrode, and polymerizing polymerizable monomers in the electrolyte solution at the surface of the first electrode 22 to form the carrier assist layer 23, as shown in e in FIG. 2.

The carrier assist layer may be a film layer having a carrier injection or carrier transport function, such as a hole injection layer, a hole transport layer, an electron injection layer, or an electron transport layer, which is not limited in the disclosure.

In this embodiment, the material of the carrier assist layer 23 is a polymer of polymerizable monomers.

In this embodiment, any material in which the monomer is electrochemically active and the polymer is conductive may serve as the material of the carrier assist layer 23, which is not limited in the disclosure.

Electrochemical polymerization refers to a polymerization reaction in which polymerizable monomers are oxidized or reduced or decomposed into free radicals or ions and the like on an electrode through electrochemical electrolysis in an electrolytic cell with an electrolyte solution.

In this embodiment, the electrolyte solution includes polymerizable monomers that are electrochemically active and may contain a substituted or unsubstituted electrochemically active group.

Alternatively, the electrolyte solution may further include a mixed solution of diethyl ether and boron trifluoride diethyl ether. The diethyl ether is a solvent, and the boron trifluoride diethyl ether is an electrolyte. Alternatively, a volume ratio of the diethyl ether to the boron trifluoride diethyl ether may be, for example, 4:1, which may be set according to actual needs.

Alternatively, a concentration of the polymerizable monomers in the electrolyte solution (i.e., monomer concentration) may be greater than or equal to 0.01 mol/L and less than or equal to 0.5 mol/L, which is not limited in the disclosure. For example, the monomer concentration may be 0.02 mol/L, 0.04 mol/L, etc.

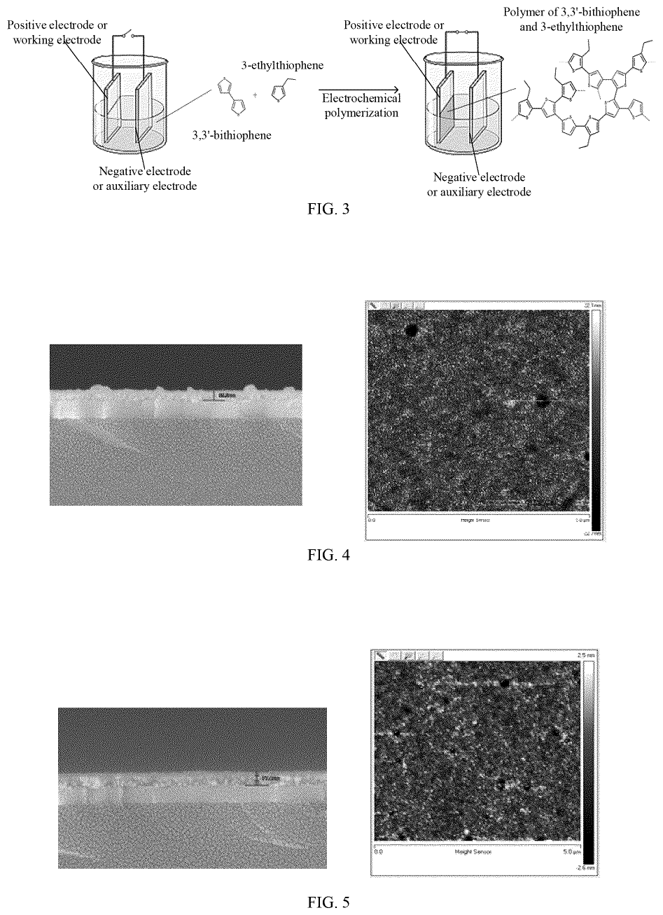

Referring to FIG. 3, a schematic diagram of preparation of a carrier assist layer with an electrochemical polymerization method is schematically shown. As shown in FIG. 3, a two-electrode system may be provided in the electrolytic cell, where the first electrode 22 on the substrate 21 is a positive electrode, and a negative electrode opposite the positive electrode is further provided in the electrolytic cell. A three-electrode system may be provided in the electrolytic cell as well, where the first electrode 22 on the substrate 21 is a working electrode, an auxiliary electrode opposite the working electrode is further provided in the electrolytic cell, and a reference electrode (not shown in FIG. 3) with a stable and maintainable potential may also be provided in the three-electrode system.

A material of the negative electrode and the auxiliary electrode may be a metal, a metal alloy or a non-metal conductor with stable electrochemical properties. For example, the material of the negative electrode and the auxiliary electrode may be metal platinum or the like. During the electrochemical reaction, a current flows between the positive electrode and the negative electrode, or between the working electrode and the auxiliary electrode, which are arranged opposite each other respectively.

In particular implementations, the electrochemical polymerization method may employ any of a constant potential mode, a constant current mode, and a pulsed polarization mode. The constant potential mode is to apply a constant potential to the positive electrode, i.e., the first electrode 22; the constant current mode is to apply a constant current to the positive electrode, i.e., the first electrode 22; and the pulsed polarization mode is to apply a pulsed periodic voltage to the positive electrode, i.e., the first electrode 22. For example, when a constant potential is applied to the positive electrode, i.e., the first electrode 22, the constant potential may be greater than or equal to 0.5 V and less than or equal to 5 V.

The polymerizable monomers shown in FIG. 3 include 3-ethylthiophene and 3,3′-bithiophene, the chemical formulas of which are shown in FIG. 3. The electrochemical polymerization uses the potential on the positive electrode, i.e., the first electrode 22, as an initiation force and driving force for the polymerization reaction, so that the polymerizable monomers undergo an oxidation reaction and polymerize to form a film at the surface of the first electrode 22; the material of the film layer is a polymer of 3-ethyltbiophene and 3,3′-bithiophene, the chemical formulas of which are shown in FIG. 3.

Referring to FIG. 4, a sectional view and a surface view of the carrier assist layer 23 prepared with a spin coating process are schematically shown. The solution for spin coating is PEDOT: PSS. The left image in FIG. 4 is a sectional image of the carrier assist layer 23 captured by a scanning electron microscope, and it can be seen from the left image that the surface of the film layer has many protrusions, and the film layer is not sufficiently dense or flat. The right image in FIG. 4 is a surface image of the carrier assist layer 23 captured by an atomic force microscope, and it can be seen from the right image that the surface of the film layer has large cavities, with a diameter of up to 100 nm, a depth of up to 40 nm, and a surface roughness of up to 5.9 nm. It can be seen from FIG. 4 that the carrier assist layer 23 prepared with the solution method has poor density and has many defects.

FIG. 5 schematically shows a sectional view and a surface view of the carrier assist layer 23 prepared with an electrochemical polymerization method. The polymerizable monomers are mixed monomers of 3-ethylthiophene and 3,3′-bithiophene. The left image in FIG. 5 is a sectional image of the carrier assist layer 23 captured by a scanning electron microscope, and it can be seen from the left image that the surface of the film layer is dense and flat. The right image in FIG. 5 is a surface image of the carrier assist layer 23 captured by an atomic force microscope, and it can be seen from the right image that the surface of the film layer is flat without cavities, with an overall surface roughness of 0.56 mm. It can be seen from FIG. 5 that the carrier assist layer 23 prepared with the electrochemical polymerization process is dense and defect-free.

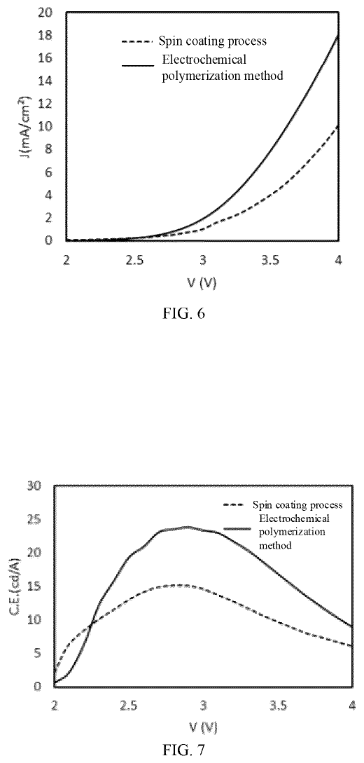

FIG. 6 shows a graph comparing current densities of light-emitting devices prepared with a spin coating process and an electrochemical polymerization method, respectively. It can be seen from FIG. 6 that the current density of the light-emitting device prepared with the electrochemical polymerization method is significantly improved as compared with that of the light-emitting device prepared with the spin coating process, because the carrier assist layer 23 prepared with the electrochemical polymerization method is dense and defect-free, facilitating hole injection and transport.

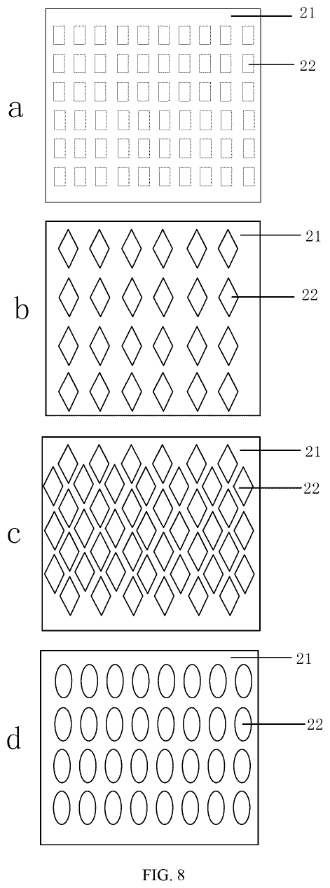

FIG. 7 shows a graph comparing current efficiencies of light-emitting devices prepared with a spin coating process and an electrochemical polymerization method, respectively. It can be seen from FIG. 7 that the current efficiency of the light-emitting device prepared with the electrochemical polymerization method is significantly improved as compared with that of the light-emitting device prepared with the spin coating process, because the carrier assist layer 23 prepared with the electrochemical polymerization has a higher hole injection efficiency and transmission rate, which improves the carrier injection balance in the light-emitting device, thus greatly improving emission efficiency of the device.

The light-emitting device prepared with the spin coating process specifically refers to preparing the carrier assist layer 23 in the light-emitting device with the spin coating process.

The light-emitting device prepared with the electrochemical polymerization method specifically refers to preparing the carrier assist layer 23 in the light-emitting device with the electrochemical polymerization method.

The carrier assist layer 23 prepared with the preparation method provided in this embodiment has greater density, higher adhesion, fewer defects, higher molecular weight, better thermal stability, and higher carrier transport rate, as compared with a film layer prepared with a spin coating process or a thermal annealing process in the related art.

The preparation method of a light-emitting device provided in this embodiment uses the first electrode 22 on the substrate 21 as the positive electrode or the working electrode, and adopts the electrochemical polymerization method to polymerize polymerizable monomers in the electrolyte solution at the surface of the first electrode 22 to form the carrier assist layer 23. The carrier assist layer 23 formed in this way bas a high uniformity, thus facilitating the preparation of subsequent film layers; the whole preparation process does not require complicated chemical reactions, purification, film re-formation or other steps, and the process is simple, which enables a clean production: a dense, stable and mechanically strong carrier assist layer 23 may be prepared to prevent erosion, swelling and destruction in subsequent solution processing.

In particular implementations, by adjusting electrolyte solution composition and related process parameters such as the potential on the first electrode 22, duration of electrochemical polymerization, etc., carrier assist layers 23 of different structures and properties may be obtained to accommodate different application needs.

The thickness of the carrier assist layer 23 may be controlled by parameters such as duration of electrochemical polymerization, monomer concentration, potential on the first electrode 22, etc. With the preparation method provided in this embodiment, the carrier assist layer 23 may be prepared in a thickness ranging from a monolayer to a micron level. For example, the carrier assist layer 23 may have a thickness that is greater than or equal to 5 nm and less than or equal to 20 mm. The thickness of the carrier assist layer 23 can be adjusted according to actual needs, which is not limited in the disclosure.

Alternatively, the step of forming the carrier assist layer 23 in Step 103 may specifically include: forming the carrier assist layer 23 under protection of an inert gas atmosphere. In particular implementations, inert gas atmosphere protection may be achieved by introducing an inert gas, such as nitrogen, to the electrolytic cell. Since the oxygen in the air has a polymerization inhibition effect, the influence of the oxygen may be eliminated by the inert gas atmosphere protection, and thus the polymerization conversion rate may be increased.

In the related art, it is difficult to develop a hole injection layer and the prepared hole injection layer has problems such as poor density. Therefore, when the carrier assist layer 23 is a hole injection layer, the film layer quality of the hole injection layer may be improved more significantly, improving device performance and reducing process complexity.

In an alternative implementation, the polymerizable monomers may include at least one of thiophenes and derivatives thereof.

Since the carrier assist layer 23 is a polymer of polymerizable monomers, the material of the carrier assist layer 23 is polythiophene and derivatives thereof in this implementation, so that the carrier assist layer 23 has high conductivity, stability, and high carrier injection or transport performance. Compared with the method of preparing the carrier assist layer 23 with solution processing, this implementation does not require a long alkyl chain and a co-solvent to improve the solubility of the material, and the molecular chains of polythiophene and derivatives thereof prepared with the electrochemical polymerization method may be aligned, which may perfectly retain excellent electrical properties of polythiophene and derivatives thereof, improve carrier transmission rate and improve device performance.

Specifically, the polymerizable monomers include at least one of the thiophenes and derivatives thereof including 3,4-dibromothiophene, 3-dodecylthiophene, α-terthiophene, 3-bromo-4-methylthiophene, 3-hexylthiopbene, 3-methoxythiophene, 3-acetylthiophene, 3-ethylthiophene, 3,4-ethylenedioxythiophene, 3-methoxythiophene, 3-thiophenemalonic acid, thiopbene-3-ethyl acetate, 3-bromothiophene, trans-3-(3-thienyl) acrylic acid, 3-iodothiophene, 3-n-bexadecylthiopbene, thiophene-3-carbonitrile, 3-chlorothiophene, methyl 3-thiophenecarboxylate, 3-thiophenemethylamine, 3-butylthiophene, 3-bromomethylthiophene, 3-thiophenecarbaldehyde, 3-methylthiophene, 3-thiophenecarboxylic acid, 3-n-octadecylthiopbene. 4-aminobenzothiophene, 3-n-undecylthiophene, thiophene-3-acetonitrile. 3-n-propylthiopbene, 3,3′-bithiophene, 2,2′-dithiophene, 3-ethynylthiophene, 3-(aminomethyl) thiophene hydrochloride, 3,4-dicyanothiophene, 3,4-thiophenedicarboxylic acid, 3-heptylthiophene, 3-n-octylthiophene, 3-thiophenemethanol and trithiophene.

For example, the polymerizable monomers may be mixed monomers of 3-ethylthiophene and 3,3′-bithiophene. Referring to FIG. 3, chemical formulas of mixed monomers of 3-ethylthiophene and 3,3′-bitbiophene and a polymer thereof (i.e., the material of the carrier assist layer 23) are shown.

In particular implementations, monomers of one or more different thiophenes and derivatives thereof may be combined and polymerized to form carrier assist layers 23 with different compositions. Different compositions of the carrier assist layers 23 may lead to different conductivities. For example, when the concentration of the monomer containing a side chain is high or the side chain is long, the prepared carrier assist layer 23, such as the hole injection layer, has a poor hole injection property and slow carrier transport rate; when the concentration of the monomer containing the side chain is low or the side chain is short, the prepared hole injection layer has a good hole injection property and fast carrier transport rate.

As shown in FIG. 3, 3-ethylthiophene is a monomer containing a side chain, i.e., an alkyl chain, and if the proportion of the 3-ethylthiophene monomer is high or the alkyl chain is long, a hole injection layer with poor conductivity may be prepared; if the proportion of the 3-ethyltbiophene monomer is low or the alkyl chain is short, a hole injection layer with good conductivity may be prepared.

The above preparation method is described in detail below by taking the substrate 21 as glass, the material of the first electrode 22 as indium tin oxide, the carrier assist layer 23 as a bole injection layer, and the monomers in the electrolytic cell as mixed monomers of 3-ethylthiophene and 3,3′-bithiophene. A mixing ratio of the 3-ethylthiophene to the 3,3′-bithiophene is 1:1. Specifically, the following steps are included:

First Step: ultrasonically cleaning the substrate 21 having the first electrode 22 with absolute ethanol and deionized water in tum for 15 minutes each and then drying it, followed by irradiating it with an ultraviolet lamp for 10 minutes, so as to improve the surface work function of the first electrode 22;

Second Step: placing the substrate 21 with the first step being completed in an electrolytic solution and connecting the first electrode 22 to a working electrode or a positive electrode, while immersing the first electrode 22 in the electrolytic solution as well. The electrolyte solution is a mixed solution of diethyl ether and boron trifluoride diethyl ether, where a volume ratio of the diethyl ether to the boron trifluoride diethyl ether is 4:1. The concentration of the above mixed monomers in the electrolyte solution is 0.02 mol/L. An inert gas is introduced into the electrolyte solution for 10 minutes and a protective atmosphere of the inert gas is maintained throughout the electrochemical reaction. A constant potential of 1.5 V is applied to the first electrode 22 and the duration of the electrochemical polymerization is 300 seconds. A transparent gray polymer is found to be deposited at the surface of the first electrode 22. The voltage application is terminated after completion, and the substrate 21 is taken out. The surface of the polymer film layer (i.e., the hole injection layer) may then be rinsed with diethyl ether to remove residual electrolyte solution and monomers; this may be followed by an annealing treatment at 80° C. for 10 minutes to remove residual solvent and complete the preparation of the hole injection layer at the surface of the first electrode 22.

In particular implementations, as shown in d in FIG. 2, the carrier assist layer 23 is a hole injection layer, and the light-emitting device described above may further include a hole transport layer 24, a light-emitting layer 25, an electron transport layer 26, an electron injection layer 27, a second electrode 28 and an encapsulation cover plate 29 which are arranged in stack on a side of the carrier assist layer 23 facing away from the substrate 21. The hole transport layer 24 is arranged adjacent to the carrier assist layer 23. It is noted that in an electroluminescent device, other film layers may be selectively provided according to actual needs except the light-emitting layer 25 and the second electrode 28.

The hole transport layer 24 mainly serves to transport holes, and materials may include, but are not limited to, organic hole transport materials such as TFB, CBP, NPB and TPD, and inorganic hole transport materials such as nickel oxide, tungsten oxide, molybdenum oxide, cuprous oxide and vanadium oxide.

The light-emitting layer 25 may include, for example, organic light-emitting materials or quantum dot materials, which is not limited in the disclosure. The quantum dot materials may include, but are not limited to, CdS, CdSe, ZnSe, InP, PbS, CsPbCl₃, CsPbBr₃, CsPhI₃, CdS/ZnS, CdSe/ZnS, InP/ZnS, PbS/ZnS, CsPbCl₃/ZnS, CsPbBr₃/ZnS, CsPhI₃/ZnS, etc.

The quantum dot materials may include a red quantum dot material, a green quantum dot material, or a blue quantum dot material, etc., thereby enabling color light-emission and color display.

The electron transport layer 26 is mainly responsible for electron transport, and materials may include, but are not limited to, zinc oxide, magnesium zinc oxide, aluminum zinc oxide, fin oxide, titanium oxide, etc.

The electron injection layer 27 mainly serves to lower the potential barrier for injecting electrons from the second electrode 28 so that electrons can be efficiently injected from the second electrode 28 into the light-emitting layer 25, and materials may include, but are not limited to, lithium fluoride, magnesium boride, magnesium fluoride, aluminum oxide, etc.

The material of the second electrode 28 may be a transparent metal oxide such as indium tin oxide, indium zinc oxide, etc., or an opaque metal such as aluminum, silver, etc. The work functions of the first electrode 22 and the second electrode 28 may be the same or different, and the first electrode 22 and the second electrode 28 are interchangeable.

The encapsulation cover plate 29 may include, for example, a glass cover plate or the like, the specific structure of which is not limited in the disclosure.

In this implementation, the first electrode 22 is the anode and the second electrode 28 is the cathode of the light-emitting device. The work function of the first electrode 22 is greater than or equal to the work function of the second electrode 28.

Accordingly, the preparation method described above may further include the following steps:

Third Step: spin coating TFB—material for the hole transport layer 24, at the surface of the carrier assist layer 23 facing away from the substrate 21, followed by annealing at 120° C. for 15 minutes to remove the solvent in the spin coating solution, so as to form the hole transport layer 24;

Fourth Step: forming the light-emitting layer 25 at the surface of the hole transport layer 24 facing away from the substrate 21. Specifically, the red quantum dot material may be first spin coated and annealed at 100° C. for 15 minutes to form a flat red quantum dot R; then the green quantum dot material is spin coated and annealed at 100° C. for 15 minutes to form a flat green quantum dot G; and then the blue quantum dot material is spin coated and annealed at 100° C.: for 15 minutes to form a flat blue quantum dot B.

The red quantum dot R. the green quantum dot G and the blue quantum dot B are insulated from each other. In a practical structure, in order to avoid a short circuit among the red quantum dot R, the green quantum dot G and the blue quantum dot B, an insulating pixel defining layer (not shown in the drawing) may be provided between quantum dots of two adjacent sub-pixels, and the structure of the pixel defining layer may be set according to actual needs.

Fifth Step: spin coating an electron transport material, such as zinc oxide, at the surface of the light-emitting layer 25 facing away from the substrate 21 followed by annealing at 100° C. for 15 minutes to form the electron transport layer 26;

Sixth Step: vacuum evaporating a material for the second electrode 28, such as aluminum, at the surface of the electron transport layer 26 facing away from the substrate 21 to form the second electrode 28;

Seventh Step: encapsulating the device structure completed in the Sixth Step with a glass cover plate to complete the preparation of the light-emitting device.

In order to obtain a patterned carrier assist layer 23, Step 102 may include, in an alternative implementation: by using a patterning process, forming a patterned first electrode 22 on a side of the substrate 21. Referring to FIG. 8, schematic diagrams of planar structures of several patterned first electrodes 22 are shown.

The orthograph shape of the patterned first electrode 22 on the substrate 21 may be, for example, a regular or irregular pattern such as a triangle, a rectangle (as shown in a in FIG. 8), a square, a trapezoid, a diamond (as shown in b and e in FIG. 8), a circle, an ellipse (as shown in d in FIG. 8), a pentagon, a hexagon, etc., which is not limited in the disclosure.

The first electrode 22 may be arranged on the substrate in an array manner (as shown in a, b, and d in FIG. 8), a staggered manner (as shown in c in FIG. 8), or other manner, which is not limited in the disclosure.

The patterning process may include, for example, a series of steps including film formation, exposure, development, and etching, etc.

Accordingly, in step 103, the step of polymerizing polymerizable monomers in the electrolyte solution at the surface of the first electrode 22 to form the carrier assist layer 23 may include: polymerizing polymerizable monomers in the electrolyte solution at the surface of the patterned first electrode 22 to form the carrier assist layer 23 in the same pattern as the first electrode 22.

Referring to FIG. 9, several patterned carrier assist layers 23 are shown. Plan a in FIG. 9 corresponds to plan a in FIG. 8, and the first electrode 22 and the carrier assist layer 23 have the same rectangular pattern arranged in an array manner. Plan b in FIG. 9 corresponds to plan b in FIG. 8, and the first electrode 22 and the carrier assist layer 23 have the same diamond pattern arranged in an array manner. Plan c in FIG. 9 corresponds to plan e in FIG. 8, and the first electrode 22 and the carrier assist layer 23 have the same diamond pattern arranged in a staggered manner. Plan d in FIG. 9 corresponds to plan d in FIG. 8, and the first electrode 22 and the carrier assist layer 23 have the same elliptical pattern arranged in an array manner.

Since the electrochemical polymerization reaction happens only at the surface of the first electrode 22, the patterning of the carrier assist layer 23 may be achieved by patterning the first electrode 22. Further, the carrier assist layer 23 has the same pattern as that of the first electrode 22, and therefore the carrier assist layer 23 may cover the surface of the first electrode 22 uniformly and entirely.

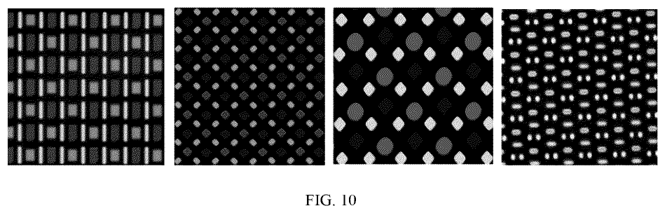

This implementation enables patterning of the carrier assist layer 23 in a single step without complicated exposure and etching processes, which is simple in process and low in cost. This implementation allows preparation of carrier assist layers 23 of various shapes and sizes to meet the needs of different shaped and sized pixels. Referring to FIG. 10, several pixel structures are shown, and this implementation may meet, but is not limited to, the design needs of the pixel structure shown in FIG. 10.

The present disclosure further provides a light-emitting device prepared with the preparation method provided by any of the embodiments.

It will be appreciated by those skilled in the art that the light-emitting device has all of the advantages of the foregoing preparation method.

Specifically, the light-emitting device includes a substrate 21, and a first electrode 22 and a carrier assist layer 23 laminated on a side of the substrate 21, the first electrode 22 being arranged adjacent to the substrate 21, as shown in c in FIG. 2.

The material of the first electrode 22 may be a transparent metal oxide such as indium tin oxide, indium zinc oxide, etc., or an opaque metal such as aluminum, silver, etc.

The carrier assist layer 23 is prepared with an electrochemical polymerization method, and the material may include, for example, polythiophene and derivatives thereof. The carrier assist layer 23 may have a thickness that is greater than or equal to 5 nm and less than or equal to 20 mm.

In order to achieve electroluminescence, the light-emitting device described above may further include a light-emitting layer 25 arranged on a side of the carrier assist layer 23 facing away from the substrate 21, and a second electrode 28 arranged on a side of the light-emitting layer 25 facing away from the substrate 21.

The light-emitting layer 25 may include, for example, organic light-emitting materials or quantum dot materials, which is not limited in the disclosure.

The quantum dot materials may include, but are not limited to, CdS, CdSe, ZnSe, InP. PbS, CsPbCl₃, CsPbBr₃, CsPhI₃, CdS/ZnS, CdSe/ZuS, InP/ZnS, PbS/ZnS, CsPbCl₃/ZnS, CsPbBr₃/ZnS, CsPhI₃/ZnS, etc.

The quantum dot materials may include a red quantum dot material, a green quantum dot material, or a blue quantum dot material, etc., thereby enabling color light-emission and color display.

The material of the second electrode 28 may be a transparent metal oxide such as indium tin oxide, indium zinc oxide, etc., or an opaque metal such as aluminum, silver, etc.

In this implementation, the first electrode 22 is the anode, the second electrode 28 is the cathode of the light-emitting device, and the carrier assist layer 23 is the hole injection layer.

In order to improve emission efficiency of the electroluminescent device, the light-emitting device described above may further include at least one of film layers including a hole transport layer 24, an electron transport layer 26, and an electron injection layer 27.

The hole transport layer 24 is arranged between the carrier assist layer 23 and the light-emitting layer 25.

The electron transport layer 26 and the electron injection layer 27 are arranged in stack between the light-emitting layer 25 and the second electrode 28, the electron transport layer 26 is arranged adjacent to the light-emitting layer 25.

The hole transport layer 24 mainly serves to transport holes, and materials may include, but are not limited to, organic hole transport materials such as CBP, NPB and TPD, and inorganic hole transport materials such as nickel oxide, tungsten oxide, molybdenum oxide, cuprous oxide and vanadium oxide.

The electron transport layer 26 is mainly responsible for electron transport, and materials may include, but are not limited to, zinc oxide, magnesium zinc oxide, aluminum zinc oxide, fin oxide, titanium oxide, etc.

The electron injection layer 27 mainly serves to lower the potential barrier for injecting electrons from the cathode so that electrons can be efficiently injected from the cathode into the light-emitting layer 25, and materials may include, but are not limited to, lithium fluoride, magnesium boride, magnesium fluoride, aluminum oxide, etc.

The present disclosure further provides a light-emitting apparatus including the light-emitting device according to any of the embodiments.

It will be appreciated by those skilled in the art that the light-emitting apparatus has the advantages of the foregoing light-emitting device.

In some embodiments, the light-emitting apparatus may be an illumination apparatus, in which case the light-emitting apparatus serves as a light source to perform an illumination function. For example, the light-emitting apparatus may be a backlight module in a liquid crystal display unit, a lamp for internal or external illumination, or various signal lamps, etc.

In other embodiments, the light-emitting apparatus may be a display unit, in which case the light-emitting device serves to perform a function of displaying images (i.e., screen). The light-emitting apparatus may include a display or a product including a display. The display may be a flat panel display (FPD), a microdisplay, or the like. The display may be a transparent display or an opaque display if divided according to whether the user can see the scene at the back of the display. The display may be a flexible display or an ordinary display (also referred to as a rigid display) if divided according to whether the display can be bent or rolled. Exemplarily, a product including a display may include a computer monitor, a television, a billboard, a laser printer with a display function, a telephone, a mobile phone, electronic paper, a personal digital assistant (PDA), a laptop computer, a digital camera, a tablet computer, a notebook computer, a navigator, a portable camcorder, a viewfinder, a vehicle, a large-area wall, a screen in a theater or a stadium signage, etc.

In the specification, various embodiments are described in a progressive manner, each of which focuses on differences from the other embodiments, and reference should be made to each other for the same or similar parts.

Finally, it is also noted that relational terms, such as first and second, are used herein solely to distinguish one entity or action from another entity or action without necessarily requiring or implying any actual such relationship or order between such entities or actions. Further, the terms “include”, “comprise”, or any other variation thereof, are intended to encompass a non-exclusive inclusion, such that a process, method, article, or device that includes a list of elements does not include only those elements but may include other elements not expressly listed or inherent to such process, method, article, or device. An element defined by the statement “include a/an . . . ” does not, without further restrictions, exclude the existence of additional identical elements in the process, method, article, or device that includes the element.

A detailed description has been given to the preparation method of a light-emitting device, the light-emitting device and the light-emitting apparatus provided by the present disclosure. While principles and implementations of the present disclosure have been illustrated herein in connection with specific examples, the description of above embodiments is intended only to facilitate an understanding of methods and core ideas of the disclosure; meanwhile, those skilled in the art will make variations to the particular implementations and the application scope, according to the ideas of the disclosure. To sum up, the contents of the specification are not construed as limiting the disclosure.

Other implementations of the disclosure will be apparent to those skilled in the art from consideration of the specification and practice of the invention disclosed herein. This disclosure is intended to encompass any variation, use, or adaptation of the disclosure following the general principles of the disclosure and including common knowledge or customary technical means, which has not been disclosed herein, in the art to which the disclosure pertains. It is intended that the specification and embodiments be considered as exemplary only, with a true scope and spirit of the disclosure being indicated by the following claims.

It is to be understood that the disclosure is not limited to the precise structure described above and shown in the accompanying drawings, and that various modifications and changes may be made without departing from the scope thereof. The scope of the present disclosure is limited only by the appended claims.

Reference herein to “an embodiment”, “embodiments”, or “one or more embodiments” means that a particular feature, structure, or characteristic described in connection with the embodiment is included in at least one embodiment of the present disclosure. In addition, it is noted that the example phrase “in an embodiment” used herein does not necessarily refer to the same embodiment throughout the document.

In the specification provided herein, numerous specific details are set forth. However, it is understood that embodiments of the disclosure may be practiced without these specific details. In some examples, well-known methods, structures and techniques have not been shown in detail in order not to obscure the understanding of the specification.

In claims, any reference signs placed between parentheses shall not be construed as limiting the claim. The word “comprise” does not exclude the presence of elements or steps not listed in a claim. The word “a” or “an” preceding an element does not exclude the presence of a plurality of such elements. The disclosure can be implemented by means of hardware including several distinct elements, and by means of a suitably programmed computer. In a unit claim enumerating several apparatuses, several of these apparatuses can be embodied by the same hardware item. The use of the words first, second, third, and the like does not denote any order. These words may be interpreted as names.

Finally, it is noted that the above embodiments are provided only to illustrate the technical solutions of the present disclosure, but not to limit them: while the present disclosure has been described in detail with reference to the foregoing embodiments, those skilled in the art will appreciate that the technical solutions disclosed in the foregoing embodiments can still be modified or some of the technical features can be substituted with equivalents, while such modifications or substitutions do not cause the essence of corresponding technical solutions to depart from the spirit and scope of the technical solutions of the embodiments of the present disclosure.

1. A preparation method of a light-emitting device, wherein the light-emitting device comprises a substrate, and a first electrode and a carrier assist layer that are arranged in stack on a side of the substrate, the first electrode is arranged adjacent to the substrate, and the preparation method comprises:
providing a substrate;
forming the first electrode on a side of the substrate, wherein the first electrode is provided with a patterned shape; and
by adopting an electrochemical polymerization method, placing the first electrode in an electrolyte solution as a positive electrode or a working electrode, and polymerizing polymerizable monomers in the electrolyte solution at the surface of the first electrode to form the carrier assist layer, wherein the material of the carrier assist layer includes a polymer of the polymerizable monomers.

2. The preparation method according to claim 1, wherein the polymerizable monomers comprise at least one of thiophenes and derivatives thereof.

3. The preparation method according to claim 2, wherein the polymerizable monomers comprise at least one of 3,4-dibromothiophene, 3-dodecylthiophene, α-terthiophene, 3-bromo-4-methylthiophene, 3-hexylthiophene, 3-methoxythiophene, 3-acetylthiophene, 3-ethylthiophene, 3,4-ethylenedioxythiophene, 3-methoxythiophene, 3-thiophenemalonic acid, thiophene-3-ethyl acetate, 3-bromothiophene, trans-3-(3-thienyl) acrylic acid, 3-iodothiophene, 3-n-hexadecylthiophene, thiophene-3-carbonitrile, 3-chlorothiophene, methyl 3-thiophenecarboxylate, 3-thiophenemethylamine, 3-butylthiophene, 3-bromomethylthiophene, 3-thiophenecarbaldehyde, 3-methylthiophene, 3-thiophenecarboxylic acid, 3-n-octadecylthiophene, 4-aminobenzothiophene, 3-n-undecylthiophene, thiophene-3-acetonitrile, 3-n-propylthiophene, 3,3′-bithiophene, 2,2′-dithiophene, 3-ethynylthiophene, 3-(aminomethyl) thiophene hydrochloride, 3,4-dicyanothiophene, 3,4-thiophenedicarboxylic acid, 3-heptylthiophene, 3-n-octylthiophene, 3-thiophenemethanol and trithiophene.

4. The preparation method according to claim 1, wherein the electrolyte solution further comprises a mixed solution of diethyl ether and boron trifluoride diethyl ether, wherein a volume ratio of the diethyl ether to the boron trifluoride diethyl ether is 4:1.

5. The preparation method according to claim 1, wherein a concentration of the polymerizable monomers in the electrolyte solution is greater than or equal to 0.01 mol/L, and less than or equal to 0.5 mol/L.

6. The preparation method according to claim 1, wherein a potential on the first electrode is a constant potential, and the constant potential is greater than or equal to 0.5 V, and less than or equal to 5 V.

7. The preparation method according to claim 1, wherein the electrolyte solution is further provided with a negative electrode corresponding to the positive electrode, or an auxiliary electrode corresponding to the working electrode, wherein the material of the negative electrode and the auxiliary electrode is a metal, a metal alloy or a non-metal conductor with stable electrochemical properties.

8. The preparation method according to claim 1, wherein forming the carrier assist layer comprises: forming the carrier assist layer under protection of an inert gas atmosphere.

9. The preparation method according to claim 1, wherein the step of forming the first electrode on a side of the substrate comprises:
by using a patterning process, forming a patterned first electrode on a side of the substrate;
the step of polymerizing polymerizable monomers in the electrolyte solution at the surface of the first electrode to form the carrier assist layer comprises:
polymerizing polymerizable monomers in the electrolyte solution at the surface of the patterned first electrode to form the carrier assist layer in the same pattern as the first electrode.

10. A light-emitting device, wherein the light-emitting device is prepared with the preparation method according to claim 1.

11. The light-emitting device according to claim 10, wherein a thickness of the carrier assist layer is greater than or equal to 5 nm, and less than or equal to 20 nm.

12. The light-emitting device according to claim 10, further comprising a light-emitting layer arranged on a side of the carrier assist layer away from the substrate, and a second electrode arranged on a side of the light-emitting layer away from the substrate.

13. The light-emitting device according to claim 12, further comprising at least one of following film layers: a hole transport layer, an electron transport layer, and an electron injection layer; wherein
the hole transport layer is arranged between the carrier assist layer and the light-emitting layer; and
the electron transport layer and the electron injection layer are arranged in stack between the light-emitting layer and the second electrode, and the electron transport layer is arranged adjacent to the light-emitting layer.

14. The light-emitting device according to claim 12, wherein the material of the light-emitting layer comprises quantum dots.

15. A light-emitting apparatus, comprising the light-emitting device according to claim 10.
